(19) United States
(12) Patent Application Publication
(10) Pub. No.: US 2018/0319129 A1
(43) Pub. Date: Nov. 8, 2018

(54) MULTILAYER BODY AND ELECTRONIC COMPONENT

(71) Applicant: Murata Manufacturing Co., Ltd., Nagaokakyo-shi (JP)

(72) Inventors: Sadaaki Sakamoto, Nagaokakyo-shi (JP); Yasutaka Sugimoto, Nagaokakyo-shi (JP)

(21) Appl. No.: 16/031,369

(22) Filed: Jul. 10, 2018

Related U.S. Application Data
(63) Continuation of application No. PCT/JP2016/073579, filed on Aug. 10, 2016.

(30) Foreign Application Priority Data
Jan. 13, 2016 (JP) 2016-004468

(51) Int. Cl. B32B 17/06; H05K 1/03; H05K 1/05; H05K 3/46

(52) U.S. Cl. CPC B32B 17/061; H05K 3/4605; H05K 1/05; H05K 1/0306

(57) ABSTRACT

A multilayer body that includes a multilayer structure having a surface layer portion and an inner layer portion. Each of the surface layer portion and the inner layer portion contains glass and quartz. The glass contained in each of the surface layer portion and the inner layer portion contains SiO₂, B₂O₃, and M₂O, where M is an alkali metal, and the quartz content in the surface layer portion is less than the quartz content in the inner layer portion.

### CROSS REFERENCE TO RELATED APPLICATIONS

The present application is a continuation of International application No. PCT/JP2016/073579, filed Aug. 10, 2016, which claims priority to Japanese Patent Application No. 2016-004468, filed Jan. 13, 2016, the entire contents of each of which are incorporated herein by reference.

### FIELD OF THE INVENTION

The present invention relates to a multilayer body and an electronic component.

### BACKGROUND OF THE INVENTION

In recent years, multilayer ceramic substrates including three-dimensionally arranged wiring conductors have been widely applied to modules in which a plurality of electronic components, such as semiconductor devices, have been disposed.

Patent Document 1 discloses a multilayer ceramic substrate having a multilayer structure composed of a surface layer portion and an inner layer portion, wherein the surface layer portion and the inner layer portion each contain a SiO₂-based crystal phase and the proportion of the SiO₂-based crystal phase in the surface layer portion is less than the proportion of the SiO₂-based crystal phase in the inner layer portion. Meanwhile, Patent Document 2 discloses a multilayer ceramic substrate having a multilayer structure composed of a surface layer portion and an inner layer portion, wherein the thermal expansion coefficient of the surface layer portion is less than the thermal expansion coefficient of the inner layer portion, the difference in thermal expansion coefficient between the surface layer portion and the inner layer portion is 1.0 ppmK⁻¹ or more, and the weight proportion of a component common to the material of the surface layer portion and the material of the inner layer portion is 75% by weight or more. According to the multilayer ceramic substrates described in Patent Documents 1 and 2, compressive stress is generated in the surface layer portion during cooling after firing by setting the thermal expansion coefficient of the surface layer portion to be less than the thermal expansion coefficient of the inner layer portion and, as a result, the flexural strength of the multilayer ceramic substrate can be improved.

Patent Document 1: Japanese Unexamined Patent Application Publication No. 2008-53525

Patent Document 2: International Publication No. 2007/142112

### SUMMARY OF THE INVENTION

In order to address size reduction and higher-frequency operation of an electronic component including a multilayer ceramic substrate, the relative permittivity of an insulating portion that constitutes the electronic component has to be decreased. This is because a loss due to an eddy current generated in a ground electrode can be reduced by decreasing the relative permittivity while the loss cannot be ignored as size reduction and higher-frequency operation of an electronic component advances. However, according to the configurations described in Patent Documents 1 and 2, while the strength is high, the relative permittivity of the insulating portion is not adequately low. As a result, there is a problem in that the above-described loss is significant.

The present invention was realized so as to solve the above-described problem, and it is an object to provide a multilayer body having high strength and low relative permittivity.

In order to achieve the above-described object, a multilayer body according to an aspect of the present invention includes a multilayer structure having a surface layer portion and an inner layer portion, wherein each of the surface layer portion and the inner layer portion contains glass and quartz, the glass contained in each of the surface layer portion and the inner layer portion contains SiO₂, B₂O₃, and M₂O (where M is an alkali metal), and a first quartz content Ws in the surface layer portion is less than a second quartz content Wi in the inner layer portion.

In the multilayer body according to an aspect of the present invention, the glass containing SiO₂ and the quartz are contained in both the surface layer portion and the inner layer portion. All these materials have low relative permittivity and, therefore, the relative permittivity of the surface layer portion and the relative permittivity of the inner layer portion can be decreased.

Further, the glass containing an alkali metal oxide (M₂O), e.g., Li₂O, is used in the surface layer portion and the inner layer portion. Therefore, the viscosity of the glass can be decreased, and a dense sintered body can be produced. In particular, the viscosity of the glass can be decreased by addition of a small amount of M₂O compared with the case where an alkaline earth metal oxide, e.g., CaO, is used. Therefore, the SiO₂ content in the glass can be increased, and the relative permittivity of the surface layer portion and the relative permittivity of the inner layer portion can be decreased.

In addition, the thermal expansion coefficient of the glass is about 6 ppm° C.⁻¹, whereas the thermal expansion coefficient of the quartz serving as a filler is about 12 ppm° C.⁻¹. Therefore, the thermal expansion coefficient of the surface layer portion can be made to be less than the thermal expansion coefficient of the inner layer portion by setting the quartz content in the surface layer portion to be less than the quartz content in the inner layer portion. Consequently, a compressive stress is generated in the surface layer portion during cooling after firing and, as a result, the flexural strength of the multilayer body can be improved.

Regarding the multilayer body according to an aspect of the present invention, the SiO₂ content in the glass contained in each of the surface layer portion and the inner layer portion is preferably 55% by weight or more. When the SiO₂ content in the glass is 55% by weight or more, the relative permittivity can be decreased. Also, when the glass containing an alkali metal oxide is used for the surface layer portion and the inner layer portion, even when the SiO₂ content in the glass is 55% by weight or more, a dense sintered body can be produced.

Regarding the multilayer body according to an aspect of the present invention, the M₂O content in the glass contained in each of the surface layer portion and the inner layer portion is preferably 10% by weight or less. When the M₂O content in the glass is 10% by weight or less, the SiO₂ content can be increased and, thereby, the relative permittivity can be decreased. In addition, even when the M₂O content in the glass is 10% by weight or less, the viscosity of the glass can be decreased in contrast to the case where an alkaline earth metal oxide is used.

Regarding the multilayer body according to an aspect of the present invention, a difference between the second quartz content Wi and the first quartz content Ws is preferably 2% by weight or more. When the difference in quartz content between the surface layer portion and the inner layer portion is 2% by weight or more, the difference in thermal expansion coefficient can be increased and, as a result, the flexural strength of the multilayer body can be improved.

The multilayer body according to the present invention may be a multilayer ceramic substrate or a chip component.

An electronic component according to the present invention includes the above-described multilayer body.

According to the present invention, a multilayer body having high strength and low relative permittivity can be provided.

### BRIEF DESCRIPTION OF THE DRAWINGS

FIG. 1 is a schematic sectional view showing an electronic component including a multilayer ceramic substrate.

FIG. 2 is a sectional view showing an unfired multilayer sheet body prepared midway through production of the multilayer ceramic substrate shown in FIG. 1.

FIG. 3 is a schematic perspective view showing an LC filter as an example of a chip component.

FIG. 4 is a schematic plan view showing a pattern printed on a green sheet constituting a sample for evaluating insulation reliability.

FIG. 5 is a schematic sectional view showing a sample for evaluating insulation reliability.

FIG. 6 is a schematic perspective view showing a sample for evaluating insulation reliability.

### DETAILED DESCRIPTION OF THE PREFERRED EMBODIMENTS

A multilayer body and an electronic component according to aspects of the present invention will be described below.

However, the present invention is not limited to the configuration described below and can be appropriately modified and applied to various configurations. The present invention also encompasses combinations of at least two of the individual desirable configurations of the present invention described below.

It should be noted that each of the embodiments described below is an exemplification and that configurations shown in different embodiments can be partly replaced or combined with each other. In the second and subsequent embodiments, descriptions of items common to the first embodiment will not be provided and only different points will be described. In particular, the same or similar operations and advantages due to the same or similar configurations will not be described in all embodiments.

### First Embodiment: Multilayer Ceramic Substrate

The multilayer body according to the present invention can be applied to a multilayer ceramic substrate.

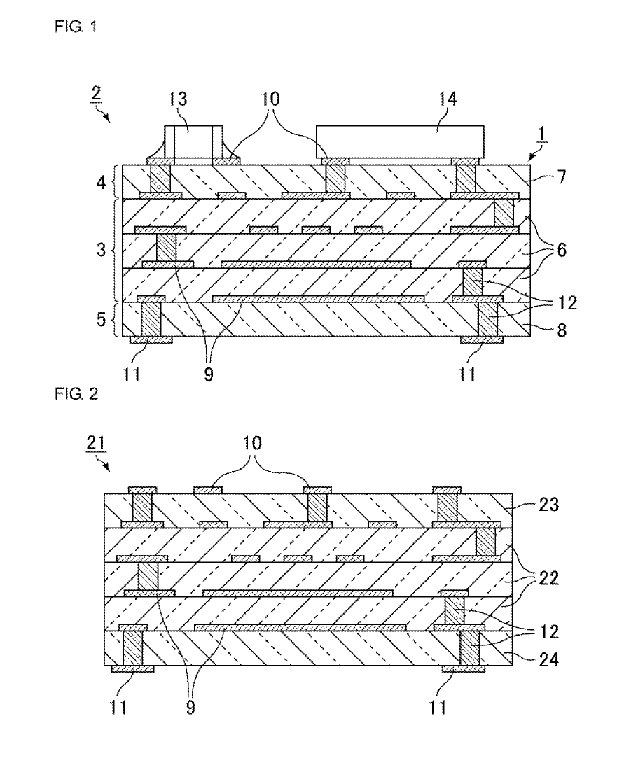

FIG. 1 is a schematic sectional view showing an electronic component including a multilayer ceramic substrate. A multilayer ceramic substrate 1 has a multilayer structure composed of an inner layer portion 3, a first surface layer portion 4, and a second surface layer portion 5, where the first surface layer portion 4 and the second surface layer portion 5 are located so as to interpose the inner layer portion 3 therebetween in the stacking direction. The inner layer portion 3 is composed of at least one inner layer portion ceramic layer 6. The first surface layer portion 4 includes at least one surface layer portion ceramic layer 7, and the second surface layer portion 5 includes at least one surface layer portion ceramic layer 8.

The multilayer ceramic substrate 1 includes wiring conductors. For example, the wiring conductors constitute passive elements, e.g., a capacitor or a inductor, or provide connection wiring such as electrical connections between elements. Typically, as shown in the drawing, the wiring conductors are composed of some conductor films 9, 10, and 11 and some via hole conductors 12. Preferably, these wiring conductors contain silver or copper as a primary component.

The conductor films 9 are disposed inside the multilayer ceramic substrate 1. The conductor films 10 are disposed on one principal surface of the multilayer ceramic substrate 1, and the conductor films 11 are disposed on the other principal surface. The via hole conductors 12 are disposed so as to electrically connect various of the conductor films 9, 10, and 11 and to pass through the respective specific ceramic layers in the thickness direction.

Chip components 13 and 14 are shown in the state of being electrically connected to the conductor films 10 and mounted on one principal surface of the multilayer ceramic substrate 1. Consequently, an electronic component 2 including the multilayer ceramic substrate 1 is formed. The chip components 13 and 14 mounted on the multilayer ceramic substrate 1 may be a multilayer body according to a second embodiment described later. Although not shown in the drawing, conductor films 11 disposed on the other principal surface of the multilayer ceramic substrate 1 are used as electrical connection configurations when the electronic component 2 is mounted on a mother board.

Each of the surface layer portions 4, 5 and the inner layer portion 3 contains glass. Specifically, the glass contained in each of the surface layer portions and the inner layer portion contains SiO₂, B₂O₃, and M₂O (where M is an alkali metal).

The SiO₂ component in the glass contributes to a decrease in relative permittivity and to a decrease in thermal expansion coefficient. The SiO₂ content in the glass contained in each of the surface layer portion and the inner layer portion is preferably 55% by weight or more and more preferably 62% by weight or more and is preferably 95% by weight or less and more preferably 90% by weight or less.

The M₂O component in the glass contributes to a decrease in glass viscosity. There is no particular limitation regarding the type of M₂O as long as M₂O is an alkaline metal oxide, and Li₂O, K₂O, or Na₂O are preferable. Regarding M₂O, one type of alkali metal oxide may be used, or at least two types of alkali metal oxides may be used.

The M₂O content in the glass contained in each of the surface layer portions and the inner layer portion is preferably 0.1% by weight or more and more preferably 0.5% by weight or more and is preferably 10% by weight or less and more preferably 6.5% by weight or less. When at least two types of alkali metal oxides are used as M₂O, the total amount thereof is taken as the M₂O content.

The B₂O₃ component in the glass contributes to a decrease in glass viscosity. The B₂O₃ content in the glass contained in each of the surface layer portions and the inner layer portion is preferably 5% by weight or more and more preferably 7% by weight or more and is preferably 40% by weight or less and more preferably 35% by weight or less.

The glass contained in each of the surface layer portions and the inner layer portion may further contain an alkaline earth metal oxide, e.g., CaO. However, from the viewpoint of increasing the SiO₂ content in the glass, it is preferable that no alkaline earth metal oxide be contained, and even when an alkaline earth metal oxide is contained, the content thereof is preferably less than 15% by weight.

The glass contained in each of the surface layer portion and the inner layer portion may further contain Al₂O₃. In that case, the Al₂O₃ content in the glass contained in each of the surface layer portion and the inner layer portion is preferably 0.1% by weight or more and more preferably 0.2% by weight or more and is preferably 5% by weight or less and more preferably 3% by weight or less.

The glass contained in the surface layer portion and the inner layer portion may further contain other impurities. When an impurity is present, the content is preferably less than 5% by weight.

The composition of the glass contained in the surface layer portions may be different from the composition of the glass contained in the inner layer portion, but the two are preferably the same.

Each of the surface layer portions and the inner layer portion contains quartz serving as a filler. In the present specification, a filler refers to an inorganic additive that is not contained in the glass.

The quartz content in the surface layer portions is less than the quartz content in the inner layer portion. When the quartz content in the surface layer portion is Ws [% by weight] and the quartz content in the inner layer portion is Wi [% by weight], the difference in quartz content Wi−Ws is preferably 2% by weight or more and more, preferably 5% by weight or more, and is preferably 40% by weight or less, and more preferably 30% by weight or less.

The quartz content in each of the surface layer portions and the inner layer portion can be determined from the peak intensity of quartz based on X-ray diffraction (XRD).

The quartz content Ws in the surface layer portions is preferably 5% by weight or more and more preferably 10% by weight or more, and is preferably 40% by weight or less and more preferably 35% by weight or less. The quartz content Wi in the inner layer portion is preferably 10% by weight or more and more preferably 15% by weight or more, and is preferably 50% by weight or less and more preferably 45% by weight or less.

The thermal expansion coefficient of the surface layer portion can be made less than the thermal expansion coefficient of the inner layer portion by setting the quartz content in the surface layer portions to be less than the quartz content in the inner layer portion. The difference in thermal expansion coefficient between the inner layer portion and the surface layer portions is preferably 0.5 ppm° C.⁻¹ or more and more preferably 1.0 ppm° C.⁻¹ or more and is preferably 4.0 ppm° C.⁻¹ or less and more preferably 3.5 ppm° C.⁻³ or less. The thermal expansion coefficient is obtained as a value measured in the range of room temperature to 600° C. by thermomechanical analysis (TMA).

Each of the surface layer portions and the inner layer portion may contain a SiO₂ crystal (for example, cristobalite) serving as a filler other than quartz.

Also, each of the surface layer portions and the inner layer portion may contain a filler (for example, Al₂O₃ or ZrO₂) other than the SiO₂ crystal.

The multilayer ceramic substrate 1 shown in FIG. 1 is produced preferably as described below.

FIG. 2 is a sectional view showing an unfired multilayer sheet body prepared midway through production of the multilayer ceramic substrate shown in FIG. 1. An unfired multilayer sheet body 21 includes inner layer green sheets 22 serving as the inner layer portion 3 in the multilayer ceramic substrate 1 and surface layer green sheets 23 and 24 serving as the surface layer portions 4 and 5. In addition, in relation to the inner layer green sheets 22 and the surface layer green sheets 23 and 24, conductor films 9, 10, and 11 and via hole conductors 12 are disposed so as to serve as wiring conductors included in the multilayer ceramic substrate 1.

In order to produce such a multilayer sheet body 21, initially, the inner layer green sheets 22 and the surface layer green sheets 23 and 24 are prepared. The composition of each of the green sheets 22, 23, and 24 is selected such that each of the materials for constituting sintered bodies of the surface layer green sheets 23 and 24 and the inner layer green sheets 22 contains glass and quartz, each glass contained in the sintered body of each of the surface layer green sheets 23 and 24 and the inner layer green sheets 22 contains SiO₂, B₂O₃, and M₂O (M represents an alkali metal), and the quartz content in each of the sintered bodies of the surface layer green sheets 23 and 24 is less than the quartz content in the inner layer green sheets 22.

Subsequently, the multilayer sheet body 21 is fired. There is no particular limitation regarding the firing temperature, and a firing temperature of, for example, 1,000° C. or lower is adopted. In addition, there is no particular limitation regarding the firing environment. For example, it is preferable that firing be performed in an air atmosphere when a hard-to-oxidize material, e.g., silver, is used as a wiring material and that firing be performed in a low-oxygen atmosphere, e.g., a nitrogen atmosphere, when an easy-to-oxidize material, e.g., copper, is used as a wiring material. As a result, the multilayer ceramic substrate 1 shown in FIG. 1 is produced.

In this regard, constraining green sheets containing an inorganic material (Al₂O₃ or the like) that is not sintered substantially at a temperature at which the inner layer green sheets 22 and the surface layer green sheets 23 and 24 are sintered may be prepared and arranged on both principal surfaces of the unfired multilayer sheet body 21, and the multilayer sheet body 21 in this state may be fired. In this case, substantially, the constraining green sheets are not sintered during firing, shrinkage does not occur, and the constraining green sheets act on the multilayer sheet body 21 so as to suppress shrinkage in the principal surface direction. As a result, the dimensional accuracy of the multilayer ceramic substrate 1 can be improved.

### Second Embodiment: Chip Component

The multilayer body according to the present invention can be applied to not only the above-described multilayer ceramic substrate but also a chip component that is mounted on the multilayer ceramic substrate.

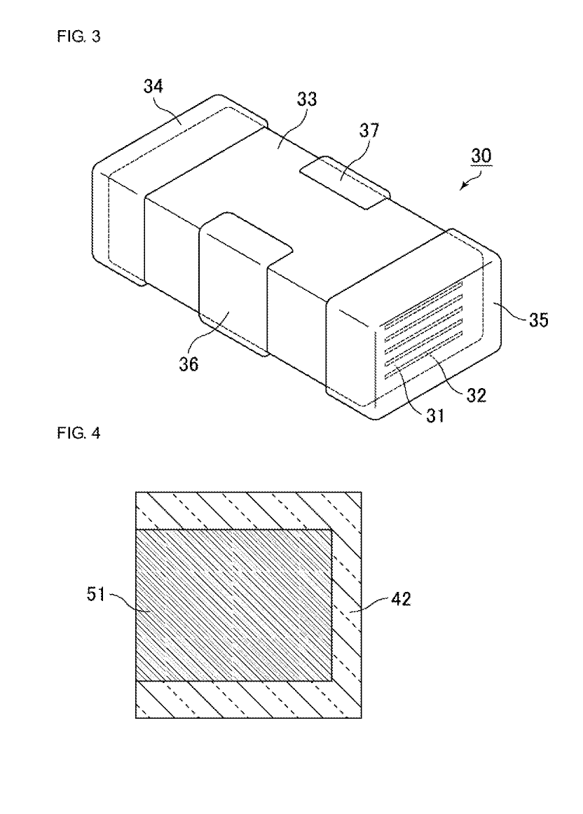

FIG. 3 is a schematic perspective view showing an LC filter as an example of the chip component. An LC filter 30 includes a component main body 33 having a structure in which a plurality of ceramic layers 31 and a plurality of inner conductor layers 32 are stacked. Terminal electrodes 34 and 35 are disposed on the outer surfaces at the respective end portions of the component main body 33, and terminal electrodes 36 and 37 are disposed at intermediate portions of the respective side surfaces.

In the LC filter 30, two inductances are formed between the terminal electrodes 34 and 35 so as to be connected in series, and a capacitance is formed between the connection point of these inductances and the terminal electrodes 36 and 37.

In the present embodiment, the LC filter 30 has the same structure as the multilayer ceramic substrate described in the first embodiment. That is, the plurality of ceramic layers 31 constituting the component main body 33 have the multilayer structure composed of a surface layer portion and an inner layer portion, each of the surface layer portion and the inner layer portion contains glass and quartz, the glass contained in each of the surface layer portion and the inner layer portion contains SiO₂, B₂O₃, and M₂O (where M is an alkali metal), and the quartz content in the surface layer portion is less than the quartz content in the inner layer portion.

Examples of chip components to which the multilayer body according to the present invention can be applied include a capacitor and an inductor in addition to LC composite components, e.g., an LC filter.

The multilayer body according to the present invention may be applied to those other than the above-described multilayer ceramic substrate and chip component.

### EXAMPLES

Examples that specifically disclose the multilayer body according to the present invention will be described below. In this regard, the present invention is not limited to these examples.

(Production of Glass Powder)

Glass raw material powders were mixed so as to obtain the glass having a composition shown in Table 1. The resulting mixture was placed into a platinum crucible, melted in an air at 1,400° C. for 30 minutes or more, and rapidly cooled so as to obtain cullet. Carbonates were used as raw materials for forming the alkali metal oxide (M₂O) and the alkaline earth metal oxide (CaO) in Table 1. The cullet was roughly ground, placed into a container together with ethanol and PSZ balls having a diameter of 5 mm, and subjected to ball milling. The grinding time was adjusted and, thereby, a glass powder having a central particle diameter of 1 μm was obtained. In this regard, the central particle diameter refers to a central particle diameter (D₅₀) measured by a laser diffraction-scattering method.

TABLE 1

| | | | M₂O | | | | |
|---|---|---|---|---|---|---|---|
| | SiO₂ | B₂O₃ | LiO₂ | K₂O | Na₂O | CaO | Al₂O₃ |
| Glass | [% by weight] | [% by weight] | [% by weight] | [% by weight] | [% by weight] | [% by weight] | [% by weight] |
| G1 | 62.0 | 35.0 | 2.5 | 0.0 | 0.0 | 0.0 | 0.5 |
| G2 | 70.0 | 23.0 | 6.5 | 0.0 | 0.0 | 0.0 | 0.5 |
| G3 | 70.0 | 29.0 | 0.5 | 0.0 | 0.0 | 0.0 | 0.5 |
| G4 | 85.0 | 12.0 | 2.5 | 0.0 | 0.0 | 0.0 | 0.5 |
| G5 | 80.0 | 18.0 | 1.5 | 0.0 | 0.0 | 0.0 | 0.5 |
| G6 | 80.0 | 18.0 | 0.0 | 1.5 | 0.0 | 0.0 | 0.5 |
| G7 | 80.0 | 18.0 | 0.0 | 0.0 | 1.5 | 0.0 | 0.5 |
| G8 | 80.0 | 18.0 | 0.5 | 0.5 | 0.5 | 0.0 | 0.5 |
| G9 | 50.0 | 35.0 | 0.0 | 0.0 | 0.0 | 14.5 | 0.5 |
| G10 | 90.0 | 7.0 | 2.5 | 0.0 | 0.0 | 0.0 | 0.5 |

(Production of Green Sheet)

A glass powder, a quartz powder (central particle diameter of 1 μm), an Al₂O₃ powder (central particle diameter of 1 μm), and a ZrO₂ powder (central particle diameter of 1 μm) in a composition shown in Table 2 were put into ethanol, and mixing was performed by a ball mill. Further, a binder solution in which polyvinylbutyral was dissolved into ethanol and a dioctyl phthalate (DOP) solution serving as a plasticizer were added so as to form a slurry. The resulting slurry was subjected to forming on a PET film by a doctor blade method and dried at 40° C. so as to produce green sheets having a thickness of 50 μm.

TABLE 2

| | | Glass | | Filler | | | Thermal expansion |
|---|---|---|---|---|---|---|---|
| | | | Content | Quartz | Al₂O₃ | ZrO₂ | coefficient |
| Sheet | Group | Type | [% by weight] | [% by weight] | [% by weight] | [% by weight] | [ppm° C.⁻¹) |
| S1 | A | G1 | 70 | 25 | 3 | 2 | 7.0 |
| S2 | A | G2 | 70 | 25 | 3 | 2 | 6.8 |
| S3 | A | G3 | 70 | 25 | 3 | 2 | 6.7 |
| S4 | A | G4 | 70 | 25 | 3 | 2 | 5.9 |
| S5 | A | G5 | 70 | 25 | 3 | 2 | 6.3 |
| S6 | A | G6 | 70 | 25 | 3 | 2 | 6.4 |
| S7 | A | G7 | 70 | 25 | 3 | 2 | 6.6 |
| S8 | A | G8 | 70 | 25 | 3 | 2 | 6.7 |
| S9 | A | G9 | 70 | 25 | 3 | 2 | 7.2 |
| S10 | A | G10 | 70 | 25 | 3 | 2 | 5.5 |
| S11 | A | G5 | 65 | 30 | 3 | 2 | 7.5 |
| S12 | A | G5 | 60 | 35 | 3 | 2 | 8.1 |
| S13 | A | G5 | 55 | 40 | 3 | 2 | 8.8 |
| S14 | B | G5 | 75 | 20 | 3 | 2 | 6.1 |
| S15 | B | G5 | 80 | 15 | 3 | 2 | 5.8 |
| S16 | B | G5 | 85 | 10 | 3 | 2 | 5.6 |
| S17 | B | G9 | 85 | 10 | 3 | 2 | 5.2 |

In Table 2, green sheets serving as inner layer portions in example 1 to example 14, comparative example 1, and comparative example 2 described later are identified as a group A, and green sheets serving as surface layer portions are identified as a group B. On the other hand, in comparative example 3, green sheets serving as a surface layer portion are included in a group A, and green sheets serving as an inner layer portion are included in a group B. Therefore, it is necessary to read group A and group B as group B and group A, respectively, only in the case of comparative example 3 in the following description.

(Production of Evaluation Sample and Evaluation)

(1) Thermal Expansion Coefficient

Green sheets of the group A or the group B were cut into 50 mm square, and 20 sheets were stacked, placed into a mold, and pressure-bonded by a press machine. The resulting pressure-bonded body was cut into 15 mm×5 mm and fired in the air at 900° C. for 30 minutes. After firing, in order to determine the sinterability, it was examined whether a fracture surface of the sintered body was permeated with an ink so as to be colored. Samples having good sinterability were subjected to measurement of an average thermal expansion coefficient in the range of room temperature to 600° C. by using a TMA apparatus. The thermal expansion coefficient of each sheet is shown in Table 2.

(2) Relative Permittivity and Dielectric Loss

Green sheets of the group A were cut into 50 mm square, and 15 sheets were stacked. One green sheet of the group B cut into 50 mm square was arranged on each of the top and bottom of the multilayer body. The resulting multilayer body was placed into a mold, pressure-bonded by a press machine, and fired in the air at 900° C. for 30 minutes. Regarding the sample after firing, the thickness was measured and the relative permittivity and the Q-value (reciprocal of dielectric loss) at 12 GHz were measured by a perturbation method. Regarding the evaluation criteria, the relative permittivity was 4.5 or less and the Q-value was 200 or more. The relative permittivity and the Q-value of each sample are shown in Table 3.

(3) Flexural Strength

Green sheets of the group A were cut into 50 mm square, and 15 sheets were stacked. One green sheet of the group B cut into 50 mm square was arranged on each of the top and bottom of the multilayer body. The resulting multilayer body was placed into a mold and pressure-bonded by a press machine. The resulting pressure-bonded body was cut into 5 mm×40 mm so as to prepare 20 samples, and firing was performed in the air at 900° C. for 30 minutes. Regarding each of the sample after firing, the thickness and the width were measured, and the flexural strength was measured by using a three-point bending tester. Regarding the evaluation criterion, the average flexural strength was 250 MPa or more. The flexural strength of each sample is shown in Table 3.

(4) Insulation Reliability

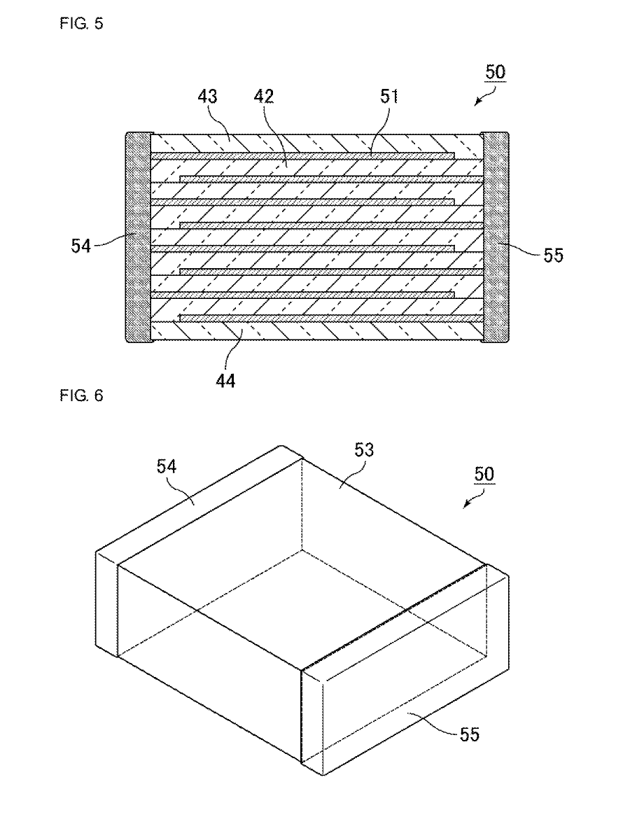

FIG. 4 is a schematic plan view showing a pattern printed on a green sheet constituting a sample for evaluating insulation reliability. In addition, FIG. 5 is a schematic sectional view showing a sample for evaluating insulation reliability, and FIG. 6 is a schematic perspective view showing a sample for evaluating insulation reliability. Initially, green sheets of the group A and the group B were cut into 20 mm square. A pattern was printed on the green sheet of the group A by using a screen printing plate and a Ag paste so as to form, on a green sheet 42, an inner electrode 51 having the pattern shown in FIG. 4. Subsequently, as shown in FIG. 5, a green sheet 44 of the group B was placed at the lowest location, 13 green sheets 42 of the group A, each provided with the inner electrode 51, were placed on the green sheet 44, where the direction of the pattern was alternately changed by 180° C., and a green sheet 43 of the group B was placed thereon so as to produce a multilayer body. The resulting multilayer body was placed into a mold and pressure-bonded by a press machine. As shown in FIG. 6, an evaluation sample 50 in which electrodes 54 and 55 were disposed on the side surfaces was produced by coating the side surfaces of a multilayer 53 with the Ag paste and performing firing in the air at 900° C. for 30 minutes.

The evaluation sample 50 after firing was subjected to a test, in which a voltage of 50 V was applied to the electrodes 54 and 55 on the opposite side surfaces, for 1,000 hours by using a constant temperature and humidity layer at a temperature of 85° C. and a humidity of 85%, and the insulation resistance after the test was measured. Regarding the evaluation criterion, the lowest insulation resistance was 10¹⁰Ω or more. In Table 3, a sample having an insulation resistance of 10¹⁰Ω or more is indicated by O, and a sample having an insulation resistance of less than 10¹⁰Ω is indicated by x.

TABLE 3

| | Surface layer | Inner layer | Difference in | Relative | Q- | Flexural strength | Insulation | |
|---|---|---|---|---|---|---|---|---|
| | portion | portion | quartz content | permittivity | value | [MPa] | reliability | Remarks |
| Example 1 | S14 | S5 | 5 | 3.8 | 330 | 250 | ○ | — |
| Example 2 | S15 | S5 | 10 | 3.8 | 350 | 300 | ○ | — |
| Example 3 | S16 | S5 | 15 | 3.7 | 320 | 350 | ○ | — |
| Example 4 | S16 | S1 | 15 | 4.3 | 270 | 320 | ○ | — |
| Example 5 | S16 | S2 | 15 | 4.2 | 230 | 300 | ○ | — |
| Example 6 | S16 | S3 | 15 | 4.2 | 260 | 310 | ○ | — |
| Example 7 | S16 | S4 | 15 | 3.9 | 310 | 350 | ○ | — |
| Example 8 | S16 | S6 | 15 | 3.8 | 300 | 290 | ○ | — |
| Example 9 | S16 | S7 | 15 | 3.8 | 290 | 300 | ○ | — |
| Example 10 | S16 | S8 | 15 | 4.0 | 270 | 290 | ○ | — |
| Example 11 | S16 | S10 | 15 | 3.7 | 330 | 260 | ○ | — |
| Example 12 | S16 | S11 | 20 | 3.9 | 350 | 370 | ○ | — |
| Example 13 | S16 | S12 | 25 | 3.9 | 360 | 370 | ○ | — |
| Example 14 | S16 | S13 | 30 | 3.8 | 340 | 380 | ○ | — |
| Comparative | S16 | S9 | 15 | 6.3 | 200 | 150 | × | glass contained in |
| | | | | | | | | inner layer portion |
| example 1 | | | | | | | | contains no M₂O |
| Comparative | S17 | S5 | 15 | 5.2 | 180 | 120 | × | glass contained in |
| | | | | | | | | surface layer portion |
| example 2 | | | | | | | | contains no M₂O |
| Comparative | S11 | S14 | −10 | 3.9 | 330 | 60 | × | quartz content |
| | | | | | | | | in surface layer |
| example 3 | | | | | | | | portion is more than |
| | | | | | | | | quartz content in |
| | | | | | | | | inner layer portion |

It was ascertained from the results shown in Table 3 that, regarding example 1 to example 14 in which the glass contained in each of the surface layer portion and the inner layer portion contained SiO₂, B₂O₃, and M₂O, and the quartz content in the surface layer portion was less than the quartz content in the inner layer portion, the relative permittivity was low and the flexural strength was high. Further, it was ascertained that, regarding example 1 to example 14, the insulation reliability was excellent.

On the other hand, regarding comparative example 1 in which the glass contained in the inner layer portion contained no M₂O and comparative example 2 in which the glass contained in the surface layer portion contained no M₂O, it was ascertained that the relative permittivity was high, the flexural strength was low, and the insulation reliability was poor. When M₂O is added to the glass, even when the amount of M₂O added was small, the viscosity of the glass can be decreased, whereas when no M₂O is added to the glass, a large amount of alkaline earth metal oxide, e.g., CaO, has to be added. As a result, it is believed that the SiO₂ content in the glass decreases and, thereby, the relative permittivity increases. Meanwhile, it is believed that even when a large amount of alkaline earth metal oxide is added, sintering is inadequate, a dense sintered body is not obtained, and as a result, the flexural strength is low and the insulation reliability is poor.

Regarding comparative example 3 in which the quartz content in the surface layer portion is more than the quartz content in the inner layer portion, it was ascertained that the relative permittivity was low, while the flexural strength was low and the insulation reliability was poor. The reason for this is assumed to be that a tensile stress is generated in the surface layer portion during cooling after sintering and cracking readily occurs contrary to example 1 to example 14.

### REFERENCE SIGNS LIST

1 multilayer ceramic substrate (multilayer body)
2 electronic component
3 inner layer portion
4, 5 surface layer portion
13, 14 chip component
30 LC filter (chip component, multilayer body)
31 ceramic layer

1. A multilayer body comprising:
a multilayer structure having at least one surface layer portion and an inner layer portion,
wherein each of the at least one surface layer portion and the inner layer portion contains glass and quartz,
the glass contained in each of the at least one surface layer portion and the inner layer portion contains SiO₂, B₂O₃, and M₂O, where M is an alkali metal, and
a first quartz content Ws in the at least one surface layer portion is less than a second quartz content Wi in the inner layer portion.

2. The multilayer body according to claim 1, wherein a content of the SiO₂ in the glass contained in each of the at least one surface layer portion and the inner layer portion is 55% by weight or more.

3. The multilayer body according to claim 1, wherein the content of the SiO₂ in the glass contained in each of the at least one surface layer portion and the inner layer portion is 55% to 95% by weight.

4. The multilayer body according to claim 1, wherein the content of the SiO₂ in the glass contained in each of the at least one surface layer portion and the inner layer portion is 62% to 90% by weight.

5. The multilayer body according to claim 2, wherein a content of the M₂O in the glass contained in each of the at least one surface layer portion and the inner layer portion is 10% by weight or less.

6. The multilayer body according to claim 5, wherein a difference between the second quartz content Wi and the second quartz content Ws is 2% by weight or more.

7. The multilayer body according to claim 6, wherein the difference between the second quartz content Wi and the second quartz content Ws is 2% to 40% by weight.

8. The multilayer body according to claim 7, wherein the difference between the second quartz content Wi and the second quartz content Ws is 5% to 30% by weight.

9. The multilayer body according to claim 1, wherein a content of the M₂O in the glass contained in each of the at least one surface layer portion and the inner layer portion is 10% by weight or less.

10. The multilayer body according to claim 9, wherein a difference between the second quartz content Wi and the first quartz content Ws is 2% by weight or more.

11. The multilayer body according to claim 10, wherein the difference between the second quartz content Wi and the second quartz content Ws is 2% to 40% by weight.

12. The multilayer body according to claim 11, wherein the difference between the second quartz content Wi and the second quartz content Ws is 5% to 30% by weight.

13. The multilayer body according to claim 1, wherein a difference between the second quartz content Wi and the first quartz content Ws is 2% by weight or more.

14. The multilayer body according to claim 13, wherein the difference between the second quartz content Wi and the second quartz content Ws is 2% to 40% by weight.

15. The multilayer body according to claim 14, wherein the difference between the second quartz content Wi and the second quartz content Ws is 5% to 30% by weight.

16. The multilayer body according to claim 1, wherein a content of the B₂O₃ in the glass contained in each of the at least one surface layer portion and the inner layer portion is 5% to 40% by weight.

17. The multilayer body according to claim 16, wherein the content of the B₂O₃ in the glass contained in each of the at least one surface layer portion and the inner layer portion is 7% to 35% by weight.

18. The multilayer body according to claim 1, wherein the multilayer body is a multilayer ceramic substrate.

19. The multilayer body according to claim 1, wherein the multilayer body is a chip component.

20. An electronic component comprising the multilayer body according to claim 1.
